(19) United States
(12) Patent Application Publication
(10) Pub. No.: US 2023/0335582 A1
(43) Pub. Date: Oct. 19, 2023

(54) MEMORY DEVICE ISOLATION STRUCTURE AND METHOD

(71) Applicant: Micron Technology, Inc., Boise, ID (US)

(72) Inventors: Shivani Srivastava, Boise, ID (US); Toshihiko Miyashita, Boise, ID (US); Dan Mihai Mocuta, Boise, ID (US); Bingwu Liu, Meridian, ID (US); Stephen David Snyder, Boise, ID (US)

(21) Appl. No.: 17/720,122

(22) Filed: Apr. 13, 2022

(51) Int. Cl. H01L 29/06; H01L 29/78; H01L 27/088; H01L 29/66

(52) U.S. Cl. CPC H01L 29/0642; H01L 29/785; H01L 27/0886; H01L 29/66795

(57) ABSTRACT

Apparatus and methods are disclosed, including memory devices and systems. Example memory devices, systems and methods include semiconductor devices having two or more fins, the fins separated by one or more inter-fin trenches. An isolation structure is included adjacent to the two or more fins, the isolation structure having a depth greater than the inter-fin trench depth.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface). The memory controller can receive commands or operations from the host system in association with memory operations or instructions, such as read or write operations to transfer data (e.g., user data and associated integrity data, such as error data or address data, etc.) between the memory devices and the host device, erase operations to erase data from the memory devices, perform drive management operations (e.g., data migration, garbage collection, block retirement), etc.

The present description addresses relates generally to example structures and methods for fin structures with isolation structures separating them from other semiconductor components in an electronic device.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A-2C illustrate selected stages of manufacturing to form fin structures and isolation structures in accordance with other example embodiments.

FIG. 3 illustrates a semiconductor device in accordance with other example embodiments.

FIG. 4A-4G illustrate selected stages of manufacturing to form fin structures and isolation structures in accordance with other example embodiments.

FIG. 5A-5H illustrate selected stages of manufacturing to form fin structures and isolation structures in accordance with other example embodiments.

FIG. 6 illustrates an example method flow diagram of forming a semiconductor device in accordance with other example embodiments.

FIG. 7 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

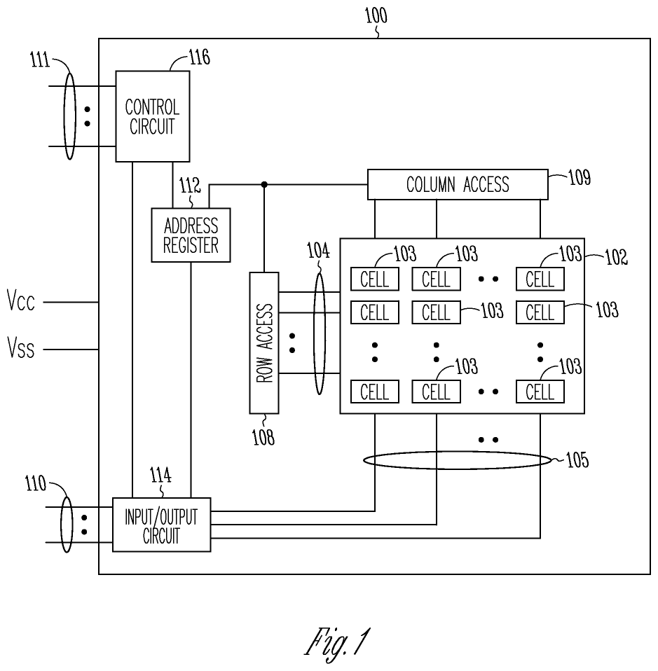

FIG. 1 shows a block diagram of an apparatus in the form of a memory device 100, that includes isolation structures according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art may recognize that memory device 100 may include other elements, several of which are not shown in FIG. 1, so as not to obscure the example embodiments described herein.

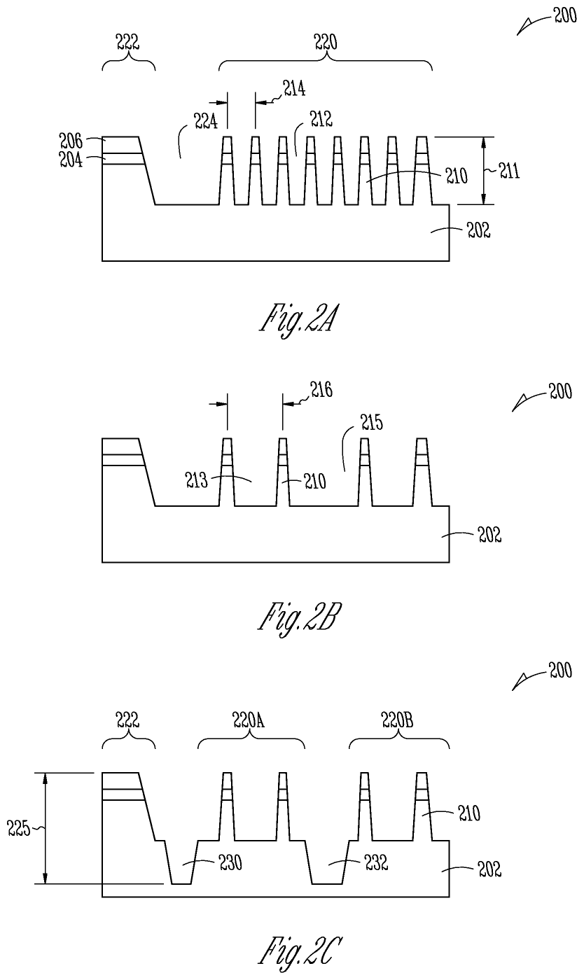

FIGS. 2A-2C show selected manufacturing stages of forming memory cells in a memory device such as shown in FIG. 1. In FIG. 2A, a number of fins 210 are shown as formed on a semiconductor substrate 202. The number of fins 210 are part of a semiconductor device 200. A first cover layer 204 and a second cover layer 206 are shown, still remaining on top of a fin region 220 and a periphery region 222. Examples of cover layers 204, 206 include oxides and nitrides. In one example, the cover layers 204, 206 are used to protect the substrate 202 from reaction during other intermediate processing operations.

The number of fins 210 are shown separated by inter-fin trenches 212 having an inter-fin trench depth 211. The number of fins 210 in FIG. 2A also illustrate a fin lithographic dimension 214 that in FIG. 2A is the same as a fin pitch 214. In semiconductor manufacturing, a minimum lithographic dimension is often used to form components, as this allows the highest density of components for a given area. FIG. 2A shows fins 210 formed at a minimum lithographic spacing 214.

FIG. 2A also illustrates a divider region 224 between the fin region 220 and the periphery region 222. In one example, as described below, the divider region 224 is used to form an isolation structure.

FIG. 2B shows the semiconductor device 200 of FIG. 2A where a number of fins 210 have been removed. In one example, the remaining fins shown in FIG. 2B are masked off, and an etch operation removes the unmasked fins. In the example shown a single fin 210 has ben removed from region 213, and two fins 210 have been removed from region 215. In one example, this leads to a fin pitch 216 of two lithographic dimensions, and a separation in region 215 of three lithographic dimensions. In one example, the remaining fins 210 in FIG. 2B are ready to be revealed (removing cover layers 204, 206) and fins 210 are ready for formation of a gate oxide and a gate over the fins 210.

FIG. 2C illustrates formation of a first isolation trench 230 and a second isolation trench 232. As shown in FIG. 2C, the first isolation trench 230 and the second isolation trench 232 have a depth 225 greater than the inter-fin trench depth 211. In one example, the first isolation trench 230 and the second isolation trench 232, as well as the inter-fin trenches 212 are later filled with a dielectric, such as an oxide material. The dielectric forms isolation structures that keeps adjacent components from unwanted electrical interference with each other.

In one example, electrical components formed in a periphery region 222 operate at higher voltages that electrical components in the fin region 220. One example includes dynamic random access (DRAM) memories with an array of memory cells formed in the fin region 220 and peripheral circuitry such as drivers and sense circuitry formed in the periphery region 222. In one example, the peripheral circuitry includes one or more planar devices that operate at 3.5 volts or higher. With higher voltages of peripheral circuitry in the periphery region 222, a deeper isolation region 230 separating the periphery region 222 from the fin region 220 provides increased reliability. A deeper isolation region 232 also helps to separate adjacent fin devices within the fin region 220.

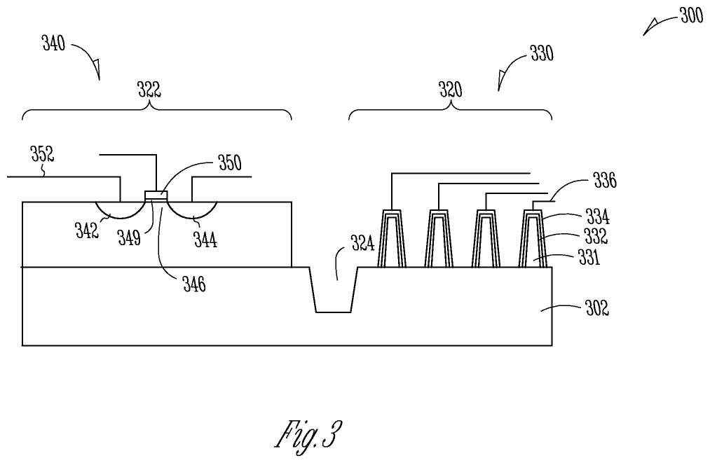

FIG. 3 illustrates a semiconductor device 300 with a planar device region 322 and a fin device region 320 separated by a divider region 324. FIG. 3 shows a planar transistor 340 in the planar device region 322, however the invention is not so limited. Other planar devices include, but are not limited to, planar capacitors, planar inductors, planar resistors, etc. Planar devices are substantially formed in two dimensions within a surface of a substrate 302. In contrast, a FinFET device, is substantially three dimensional, using vertical sides of individual fins as high surface area channels.

The planar transistor 340 shown includes a source region 342 and a drain region 344 separated by a channel region 346. A gate 350 is separated from the channel region 346 by a gate oxide 349. Planar circuitry 352 is shown as schematic lines coupling to various components of the planar transistor 340.

A number of FinFETs 330 are shown in the fin region 320. FinFET 330 includes a fin channel 331 and a gate dielectric 332 over the fin channel 331. A gate 334 is further formed over the gate dielectric 332. FinFET circuitry 336 is shown as schematic lines coupling to various components of the FinFETs 330. As discussed above, in one example the divider region 324 is filled with a dielectric material such as an oxide to provide electrical isolation between the planar transistor 340 and the FinFETs 330. In the example of FIG. 3, the divider region 324 has a depth greater than an inter-fin trench depth to provide additional electrical isolation of the planar device region 322 from the fin device region 320. As noted above, in one example, a dielectric such as an oxide is later filled within the divider region 324 to provide electrical isolation.

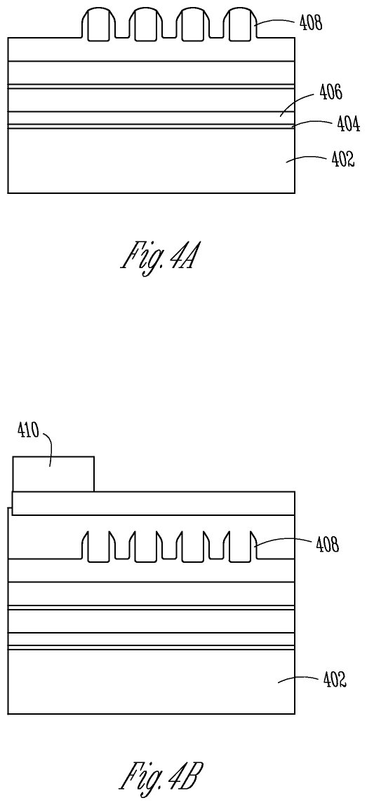

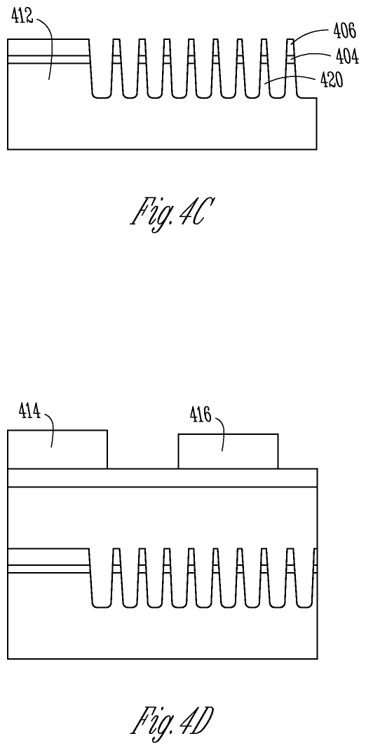

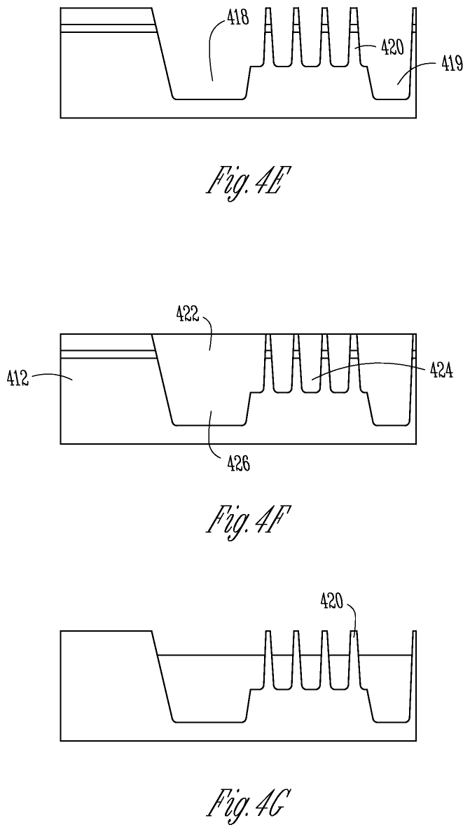

FIG. 4A-4G illustrate one example manufacturing flow to form isolation structures as described above. In FIG. 4A, a semiconductor substrate 402 is shown. A first cover layer 404 and a second cover layer 406 are shown, similar to the examples of FIGS. 2A-2C. As noted above, cover layers 404, 406 are used to protect the substrate 402 from reaction during other intermediate processing operations. A number of fin mask structures 408 are shown formed over a number of layers on the substrate 402.

In FIG. 4B, a first mask 410 is used to protect peripheral structures while the fin masks 408 remain exposed. In FIG. 4C, a number of fins 420 are formed as a result of masking from the number of fin mask structures 408. Portions of the cover layers 404, 406 remain in FIG. 4C on tops of the number of fins 420.

In FIG. 4D, second masks 414, 416 are used to selectively mask peripheral structures and middle fins in the number of fins 420. In FIG. 4E, as a result of the second masks 414, 416, a first isolation structure 418 and a second isolation structure 419 are formed on two opposite sides of a series of adjacent fins 420. In the example of FIG. 4E, selected fins in the series of adjacent fins 420 are removed from one or more ends of the series of adjacent fins 420. The removal of one or more fins from an end of the series of adjacent fins 420 can improve a consistency between fins 420 in the series. End fins 420 in a series may be affected by differing lithography conditions or other processing conditions, and as a result, the end fins 420 may be slightly different than fins 420 in a middle of a series. Chopping one or both ends of a series of adjacent fins 420 leaves only the most consistently formed fins 420 in the series.

In FIG. 4F, a dielectric 422 such as an oxide, is filled into the a first isolation structure 418 and a second isolation structure 419. The dielectric 422 is also shown filled into inter-fin trenches 424. In on example, the isolation structure 418, 419 are filled concurrently with the inter-fin trenches 424. In FIG. 4G, the cover layers 404, 406 are removed, and the fins 420 are fully exposed and ready for subsequent formation of gate dielectric layers and gate layers (not shown).

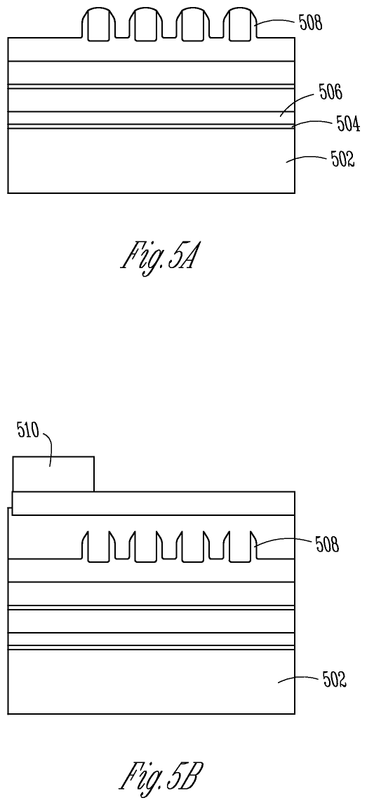

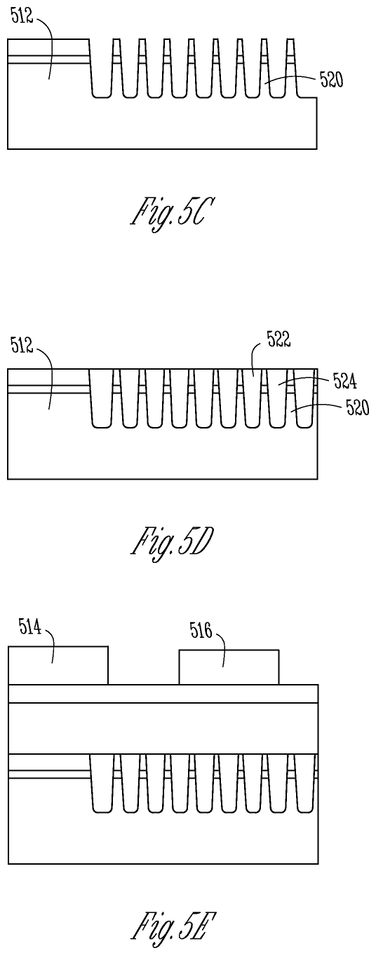

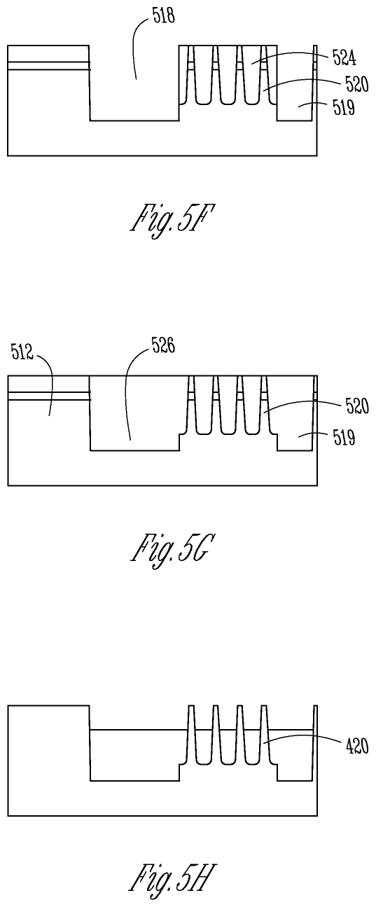

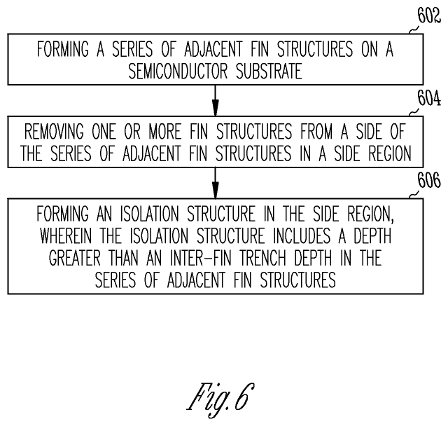

FIG. 5A-5H illustrate another example manufacturing flow to form isolation structures as described above. In FIG. 5A, a semiconductor substrate 502 is shown. Similar to FIG. 4A, a first cover layer 504 and a second cover layer 506 are shown. A number of fin mask structures 508 are shown formed over a number of layers on the substrate 502.

In FIG. 5B, a first mask 510 is used to protect peripheral region 512 while the fin masks 508 remain exposed. In FIG. 5C, a number of fins 520 are formed as a result of masking from the number of fin mask structures 508. Portions of the cover layers 504, 506 remain in FIG. 5C on tops of the number of fins 520.

In FIG. 5D, a first dielectric 522 is filled into inter-fin trenches 524. In FIG. 5E, second masks 514, 516 are used to selectively mask peripheral structures and middle fins in the number of fins 520. In FIG. 5E, as a result of the second masks 514, 516, a first isolation structure 518 and a second isolation structure 519 are formed on two opposite sides of a series of adjacent fins 520. Similar to the example of FIG. 4E, in the example of FIG. 5E, selected fins in the series of adjacent fins 520 are removed from one or more ends of the series of adjacent fins 520. As noted above, removal of end fins in a series improves the consistency between the remaining fins 520.

In FIG. 5G, a second dielectric 526 is filled into the a first isolation structure 518 and a second isolation structure 519. In one example, the second dielectric 526 is the same as the first dielectric 522. In another example, the second dielectric 526 is different from the first dielectric 522. An example of a dielectric material includes, but is not limited to, oxides.

In FIG. 5H, the cover layers 504, 506 are removed, and the fins 520 are fully exposed and ready for subsequent formation of gate dielectric layers and gate layers (not shown).

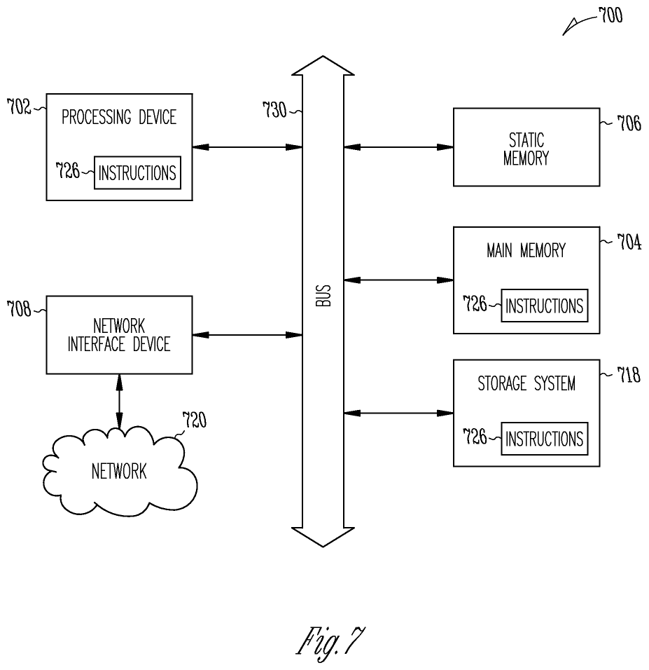

FIG. 6 shows a flow diagram of another example method of manufacture. In operation 602, a series of adjacent fin structures are formed on a semiconductor substrate. In operation 604, one or more fin structures are removed from a side of the series of adjacent fin structures in a side region. In operation 606, an isolation structure is formed in the side region, wherein the isolation structure includes a depth greater than an inter-fin trench depth in the series of adjacent fin structures.

FIG. 7 illustrates a block diagram of an example machine (e.g., a host system) 1600 which may include one or more memory devices and/or memory systems with isolation structures and other features as described above. As discussed above, machine 700 may benefit from enhanced memory performance from use of one or more of the described memory devices and/or memory systems, facilitating improved performance of machine 700 (as for many such machines or systems, efficient reading and writing of memory can facilitate improved performance of a processor or other components that machine, as described further below.

In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 700 may include a processing device 702 (e.g., a hardware processor, a central processing unit (CPU), a graphics processing unit (GPU), a hardware processor core, or any combination thereof, etc.), a main memory 704 (e.g., read-only memory (ROM), dynamic random-access memory (DRAM) such as synchronous DRAM (SDRAM) or Rambus DRAM (RDRAM), etc.), a static memory 706 (e.g., static random-access memory (SRAM), etc.), and a storage system 718, some or all of which may communicate with each other via a communication interface (e.g., a bus) 730. In one example, the main memory 704 includes one or more memory devices as described in examples above.

The processing device 702 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 702 can also be one or more special-purpose processing devices such as an application specific integrated circuit (ASIC), a field programmable gate array (FPGA), a digital signal processor (DSP), network processor, or the like. The processing device 702 can be configured to execute instructions 726 for performing the operations and steps discussed herein. The computer system 700 can further include a network interface device 708 to communicate over a network 720.

The storage system 718 can include a machine-readable storage medium (also known as a computer-readable medium) on which is stored one or more sets of instructions 726 or software embodying any one or more of the methodologies or functions described herein. The instructions 726 can also reside, completely or at least partially, within the main memory 704 or within the processing device 702 during execution thereof by the computer system 700, the main memory 704 and the processing device 702 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 700 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 700 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 726 (e.g., software, programs, an operating system (OS), etc.) or other data are stored on the storage system 718 can be accessed by the main memory 704 for use by the processing device 702. The main memory 704 (e.g., DRAM) is typically fast, but volatile, and thus a different type of storage than the storage system 718 (e.g., an SSD), which is suitable for long-term storage, including while in an “off” condition. The instructions 726 or data in use by a user or the machine 700 are typically loaded in the main memory 704 for use by the processing device 702. When the main memory 704 is full, virtual space from the storage system 718 can be allocated to supplement the main memory 704; however, because the storage system 718 device is typically slower than the main memory 704, and write speeds are typically at least twice as slow as read speeds, use of virtual memory can greatly reduce user experience due to storage system latency (in contrast to the main memory 704, e.g., DRAM). Further, use of the storage system 718 for virtual memory can greatly reduce the usable lifespan of the storage system 718.

The instructions 724 may further be transmitted or received over a network 720 using a transmission medium via the network interface device 708 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 708 may include one or more physical jacks (e.g., Ethernet, coaxial, or phone jacks) or one or more antennas to connect to the network 720. In an example, the network interface device 708 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 700, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on”(in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:

Example 1 is a semiconductor device. The semiconductor device includes two or more fins, the fins separated by one or more inter-fin trenches having an inter-fin trench depth. The semiconductor device also includes a gate dielectric over each of the two or more fins, a gate covering the gate dielectric of the two or more fins, and an isolation structure adjacent to the two or more fins, the isolation structure having a depth greater than the inter-fin trench depth.

In Example 2, the semiconductor device of Example 1 optionally includes wherein the semiconductor device includes a DRAM memory array.

In Example 3, the semiconductor device of any one of Examples 1-2 optionally includes wherein an operating voltage of at least some components of the semiconductor device is 3.5 volts or greater.

In Example 4, the semiconductor device of any one of Examples 1-3 optionally includes wherein the two or more fins include a fin lithographic dimension, and a fin pitch is one lithographic dimension.

In Example 5, the semiconductor device of any one of Examples 1-4 optionally includes wherein the two or more fins include a fin lithographic dimension, and a fin pitch is two lithographic dimensions.

In Example 6, the semiconductor device of any one of Examples 1-5 optionally includes wherein the isolation structure is a first isolation structure on a first side of the two or more fins and further including a second isolation structure on a second side of the two or more fins.

In Example 7, the semiconductor device of any one of Examples 1-6 optionally includes wherein the first and second isolation structures are two lithographic dimensions wide.

Example 8 is a semiconductor device. The semiconductor device includes a planar device formed on a semiconductor substrate. The semiconductor device includes a FinFET device formed on the semiconductor substrate adjacent the planar device, the FinFET device including, one or more fin channels, the fin channels separated by one or more inter-fin trenches having an inter-fin trench depth, a gate dielectric over each of the one or more fin channels, a gate covering the gate dielectric of the one or more fin channels, and an isolation structure separating the planar device from the FinFET device, the isolation structure having a depth greater than the inter-fin trench depth.

In Example 9, the semiconductor device of Example 8 optionally includes wherein the planar device includes a planar transistor.

In Example 10, the semiconductor device of any one of Examples 8-9 optionally includes wherein an operating voltage of the semiconductor device is 3.5 volts or greater.

In Example 11, the semiconductor device of any one of Examples 8-10 optionally includes wherein the semiconductor device includes a DRAM memory array.

In Example 12, the semiconductor device of any one of Examples 8-11 optionally includes wherein the planar device is included in a wordline driver of the DRAM array.

Example 13 is a method of forming a semiconductor device. The method includes forming a series of adjacent fin structures on a semiconductor substrate, removing one or more fin structures from a side of the series of adjacent fin structures in a side region, and forming an isolation structure in the side region, wherein the isolation structure includes a depth greater than an inter-fin trench depth in the series of adjacent fin structures.

In Example 14, the method of Example 13 optionally includes wherein forming the isolation structure in the side region includes forming a first and a second isolation structure on two opposite sides of the series of adjacent fin structures.

In Example 15, the method of any one of Examples 13-14 optionally includes wherein forming the isolation structure includes filling the inter fin trench and the isolation structure concurrently with a dielectric.

In Example 16, the method of any one of Examples 13-15 optionally includes wherein forming the isolation structure includes filling the inter fin trench first with a first dielectric, then subsequently filling the isolation structure with a second dielectric.

In Example 17, the method of any one of Examples 13-16 optionally includes wherein forming the isolation structure includes the first dielectric being the same material as the second dielectric.

In Example 18, the method of any one of Examples 13-17 optionally further includes forming a planar device on the semiconductor substrate with the isolation structure separating the series of adjacent fin structures from the planar device.

In Example 19, the method of any one of Examples 13-18 optionally includes wherein forming a series of adjacent fin structures includes forming a memory array of adjacent fin structures, and wherein forming a planar device includes forming a planar device on a periphery of the memory array.

In Example 20, the method of any one of Examples 13-19 optionally includes wherein forming a series of adjacent fin structures includes forming at a fin lithographic dimension and further including removing every other fin in the series to form a fin pitch of two lithographic dimensions.

In Example 21, the method of any one of Examples 13-20 optionally includes wherein forming an isolation structure includes forming an isolation two fin lithographic dimensions wide.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
two or more fins, the fins separated by one or more inter-fin trenches having an inter-fin trench depth;
a gate dielectric over each of the two or more fins;
a gate covering the gate dielectric of the two or more fins;
an isolation structure adjacent to the two or more fins, the isolation structure having a depth greater than the inter-fin trench depth.

2. The semiconductor device of claim 1, wherein the semiconductor device includes a DRAM memory array.

3. The semiconductor device of claim 1, wherein an operating voltage of at least some components of the semiconductor device is 3.5 volts or greater.

4. The semiconductor device of claim 1, wherein the two or more fins include a fin lithographic dimension, and a fin pitch is one lithographic dimension.

5. The semiconductor device of claim 1, wherein the two or more fins include a fin lithographic dimension, and a fin pitch is two lithographic dimensions.

6. The semiconductor device of claim 5, wherein the isolation structure is a first isolation structure on a first side of the two or more fins and further including a second isolation structure on a second side of the two or more fins.

7. The semiconductor device of claim 5, wherein the first and second isolation structures are two lithographic dimensions wide.

8. A semiconductor device, comprising:
a planar device formed on a semiconductor substrate;
a FinFET device formed on the semiconductor substrate adjacent the planar device, the FinFET device including;
one or more fin channels, the fin channels separated by one or more inter-fin trenches having an inter-fin trench depth;
a gate dielectric over each of the one or more fin channels;
a gate covering the gate dielectric of the one or more fin channels; and
an isolation structure separating the planar device from the FinFET device, the isolation structure having a depth greater than the inter-fin trench depth.

9. The semiconductor device of claim 8, wherein the planar device includes a planar transistor.

10. The semiconductor device of claim 8, wherein an operating voltage of the semiconductor device is 3.5 volts or greater.

11. The semiconductor device of claim 8, wherein the semiconductor device includes a DRAM memory array.

12. The semiconductor device of claim 8, wherein the planar device is included in a wordline driver of the DRAM array.

13. A method of forming a semiconductor device, comprising:
forming a series of adjacent fin structures on a semiconductor substrate;
removing one or more fin structures from a side of the series of adjacent fin structures in a side region; and
forming an isolation structure in the side region, wherein the isolation structure includes a depth greater than an inter-fin trench depth in the series of adjacent fin structures.

14. The method of claim 13, wherein forming the isolation structure in the side region includes forming a first and a second isolation structure on two opposite sides of the series of adjacent fin structures.

15. The method of claim 13, wherein forming the isolation structure includes filling the inter fin trench and the isolation structure concurrently with a dielectric.

16. The method of claim 13, wherein forming the isolation structure includes filling the inter fin trench first with a first dielectric, then subsequently filling the isolation structure with a second dielectric.

17. The method of claim 16, wherein forming the isolation structure includes the first dielectric being the same material as the second dielectric.

18. The method of claim 13, further including forming a planar device on the semiconductor substrate with the isolation structure separating the series of adjacent fin structures from the planar device.

19. The method of claim 13, wherein forming a series of adjacent fin structures includes forming a memory array of adjacent fin structures, and wherein forming a planar device includes forming a planar device on a periphery of the memory array.

20. The method of claim 13, wherein forming a series of adjacent fin structures includes forming at a fin lithographic dimension and further including removing every other fin in the series to form a fin pitch of two lithographic dimensions.

21. The method of claim 13, wherein forming an isolation structure includes forming an isolation two fin lithographic dimensions wide.
